(19) United States
(12) Patent Application Publication
(10) Pub. No.: US 2015/0287842 A1
(43) Pub. Date: Oct. 8, 2015

(54) PHOTOVOLTAIC SYSTEM INCLUDING LIGHT TRAPPING FILTERED OPTICAL MODULE

(71) Applicants: DOW GLOBAL TECHNOLOGIES LLC, Midland, MI (US); CALIFORNIA INSTITUTE OF TECHNOLOGY, Pasadena, CA (US)

(72) Inventors: Emily D. Kosten, Pasadena, CA (US); Christofer A. Flowers, Pasadena, CA (US); John V. Lloyd, Pasadena, CA (US); Carrie E. Hofmann, Altadena, CA (US); Harry A. Atwater, Pasadena, CA (US); Emily C. Warmann, Riverside, CA (US); James C. Stevens, Ricmond, TX (US); Rebekah K. Feist, Midland, MI (US); Weijun Zhou, Sugar Land, TX (US); Michael E. Mills, Midland, MI (US); Narayan Ramesh, Midland, MI (US)

(21) Appl. No.: 14/424,232

(22) PCT Filed: Aug. 30, 2013
(86) PCT No.: PCT/US2013/057541

§ 371 Date: Feb. 26, 2015

Related U.S. Application Data
(60) Provisional application No. 61/695,216, filed on Aug. 30, 2012.
(60) Provisional application No. 61/576,804, filed on Dec. 16, 2011.

(51) Int. Cl. H01L 31/0216; H01L 31/047

(52) U.S. Cl. CPC H01L 31/02162; H01L 31/047; H01L 31/02168

(57) ABSTRACT

A photovoltaic system that converts incident light into electrical energy that includes a light trapping optical module having a light randomizing dielectric slab with a first surface and a second surface, a first cell adjacent to the first surface of the slab that has a bandgap of lower energy than the energy of absorption onset of the dielectric slab, at least one filter element in optical contact with the second surface of the dielectric slab, and a sub-cell array with a plurality of photovoltaic sub-cells, wherein at least one of the sub-cells has a first surface that is in optical contact with the at least one filter element.

### PRIORITY

The present patent application claims priority from U.S. Provisional patent application having Ser. No. 61/695,216, filed on Aug. 30, 2012, entitled OPTICS FOR FULL SPECTRUM, ULTRAHIGH EFFICIENCY SOLAR ENERGY CONVERSION, and U.S. Provisional patent application having Ser. No. 61/756,804, filed on Jan. 25, 2013, entitled PHOTOVOLTAIC SYSTEM INCLUDING LIGHT TRAPPING FILTERED OPTICAL MODULE, wherein the entirety of said provisional patent applications is incorporated herein by reference.

### TECHNICAL FIELD

The present invention relates to photovoltaic devices that convert incident light into electrical energy. More specifically, the present invention relates to photovoltaic devices including a light trapping optical module comprising a dielectric slab coupled to a sub-cell array.

### BACKGROUND

Photovoltaic cells, which may also be referred to as solar cells or PV cells, are useful for converting incident light, such as sunlight, into electrical energy. These cells can be provided as single junction cells, for example, which are typically provided with specifically defined bandgaps that have inherently low conversion efficiencies. This is because only photons with energy above the single bandgap of the cell can be used to produce useful work, and because essentially all of the energy of a photon greater than the bandgap of the cell is thermalized into heat. Thus, a single junction is photovoltaically responsive to only a portion of the spectrum and is not very efficient for most of the wavelengths to which it responds. A number of ways of increasing the efficiency of solar cells have therefore been used and proposed.

One common method used for achieving higher photovoltaic efficiencies is to provide sunlight to multijunction solar cells rather than to single junction solar cells. Multijunction cells allow the highest energy photons to be converted by a cell with a high bandgap, thereby minimizing thermalization, while medium wavelengths go to a cell with an intermediate bandgap. The multijunction cells extend the overall spectral response by providing a bottom junction that is lower in energy than an optimum single junction cell would provide. Such multijunction solar cells are made of specific semiconductor materials whose bandgap energies are selected span the solar spectrum. Photons with energy larger than the highest bandgap are first collected by the highest energy gap sub-cell. Photons of lower energy are transmitted through the highest energy bandgap sub-cell to the sub-cell of the next highest energy bandgap. This pattern continues down to the sub-cell with the lowest energy bandgap. In this manner, the energy of absorbed photons greater than the bandgap of the absorbing cell, which is thermalized and lost as heat, is minimized. In addition, the greater number of bandgaps generally means that in an optimized case, a greater portion of the total solar spectrum is able to be absorbed by the multijunction cell as compared to a single junction cell.

Although multijunction solar cells provide advantages over single junction solar cells, further efficiency improvements can be achieved through the use of light splitting optics that are used to split the incident solar radiation and to direct the light towards different solar cells. The narrower bands of light are directed to sub-cell(s) with different bandgaps and/or to multijunction cells with differing sets of bandgaps. Each targeted sub-cell is designed to have a bandgap tailored to the spectral band directed to it in order to help optimize energy conversion. That is, the splitting optics partition the incident light into segments or slices and then direct the slices independently to photovoltaic sub-cells with appropriate bandgaps.

Photovoltaic systems that utilize spectrum-splitting optics for improving solar conversion efficiency have been described in the patent and technical literature. Examples include U.S. Pat. Publication. No. 2011/0284054 (Wanlass); Gu et al., Renewable Energy and the Environment Technical Digest, “Common-Plane Spectrum-Splitting Concentrating Photovoltaic Module Design and Development,” pp. 1-3 (2011); Imenes et al., Solar Energy Materials and Solar Cells, “Spectral Beam Splitting Technology for Increased Conversion Efficiency in Solar Concentrating Systems, A Review,” 84:19-69 (2004); Kim et al., Optics Express, “Organic Photovoltaic Cell in Lateral-Tandem Configuration Employing Continuously-Tuned Microcavity Sub-Cells,” 16(24) 19987-19994 (2008); Goetzberger et al., Solar Energy Materials and Solar Cells, “Light Trapping, a New Approach to Spectrum Splitting,” 92(12) 1570-1578 (2008); and Peters, Ian Marius, “Photonic Concepts for Solar Cells” (2009), Dissertation, Fraunhofer Institute for Solar Energy Systems.

While photovoltaic systems using spectral splitting technology with solar cells improve the efficiencies of converting incident light into electrical energy, there is a continuing need to provide systems that allow for even higher efficiencies.

### SUMMARY

The invention is directed to a photovoltaic system for converting incident light into electrical energy that may be referred to as a light trapping filtered concentrator. These systems can be used to improve the performance of solar cells so that they can achieve much higher conversion efficiencies. An embodiment of the invention generally includes a light trapping optical module having multiple photovoltaic sub-cells arranged in an array, and a dielectric slab that captures incident light and delivers captured light the photovoltaic sub-cells. The dielectric slab is made of a material having a relatively high index of refraction, such as greater than 2.0 at a wavelength of 550 nm, for example. In addition, a filter element or array is provided, which may be patterned into or deposited onto the bottom of the dielectric slab, and the sub-cells can be attached to this filter element or array. In other words, the slab bottom can be structured in a particular manner to act as a filter. Alternatively, the filter elements or array can be formed or grown on the top of the sub-cells. In either case, the filter elements can be positioned between the plurality of sub-cells and the dielectric slab to provide the desired filtering of light before the light reaches the sub-cells. The filter elements may be photonic crystals, for example, which may be patterned on the bottom surface of the slab in at least one dimension. In one example, the photonic crystal may be patterned in three-dimensions to provide interference in all directions. The light trapping optical module can also include an antireflective coating at a top surface of the dielectric slab and/or the cell positioned above the dielectric slab.

The light can be randomized within the dielectric slab so that it scatters in all directions. The randomization can occur on the top surface of the slab and/or within the slab material itself. The sub-cells of the system can be single junction or multijunction cells, such as triple junction cells. In an embodiment of the invention, the multiple sub-cells for a system can include a first group of sub-cells having a first set of bandgaps and a second group of sub-cells having a second set of bandgaps, and wherein the filter array comprises first and second filter areas that correspond to the first and second groups of sub-cells, respectively. In an exemplary embodiment, the first and second filter areas are arranged in a checkerboard type of pattern such that a first set of sub-cells is aligned with a first set of filters and a second set of sub-cells is aligned with a second set of filters.

The photovoltaic system can optionally include an optical concentrating module that may include a single optical concentrating element or multiple optical concentrating elements, wherein a system that includes multiple elements can be arranged in series in order to provide for a relatively compact optical concentrating module with relatively large levels of concentration. For one example, the optical concentrating module can include a combination of a primary optic of a Fresnel lens and a secondary optic of a compound parabolic concentrator. The output of an optical concentrating module can be a relatively small aperture, for example, which is aligned with an area of the light trapping optical module that accepts this output.

In one particular embodiment, a photovoltaic system is provided that converts incident light into electrical energy. The system includes a light trapping optical module comprising a light randomizing dielectric slab having a first surface and a second surface, and a first cell adjacent to the first surface of the dielectric slab, wherein the first cell has a bandgap of lower energy than the energy of absorption onset of the dielectric slab. The system further includes at least one filter element in optical contact with the second surface of the dielectric slab, and a sub-cell array comprising a plurality of photovoltaic sub-cells, wherein at least one of the sub-cells comprises a first surface that is in optical contact with the at least one filter element.

### BRIEF DESCRIPTION OF THE DRAWINGS

The invention will be further explained with reference to the appended Figures, wherein like structure is referred to by like numerals throughout the several views, and wherein:

FIG. 1 is a perspective view of a portion of a photovoltaic system of the invention, including optical concentration components;

FIG. 2 is an enlarged perspective view of a light trapping filtered concentrator of the type that is shown in combination the optical concentration components of FIG. 1;

FIG. 3 is an enlarged perspective view of photovoltaic cells of the type that are illustrated in FIG. 2;

FIG. 4 is an enlarged perspective view of a light trapping filtered concentrator that does not include a top absorbing cell;

FIG. 5 is a perspective view of a light trapping filtered concentrator of the invention as it can be incorporated into a printed circuit board;

FIG. 6 is a three-dimensional graph expressing the design space for maximizing optical efficiency with respect to the number of cells and index of refraction of a dielectric light trapping slab; and

FIG. 7 is a graph expressing exemplary device efficiency as a function of concentration using devices and concepts of the present invention.

### DETAILED DESCRIPTION

The embodiments of the invention described below are not intended to be exhaustive or to limit the invention to the precise forms disclosed in the following detailed description. Rather the embodiments are chosen and described so that others skilled in the art may appreciate and understand the principles and practices of the present invention. All patents, pending patent applications, published patent applications, and technical articles cited throughout this specification are incorporated herein by reference in their respective entireties for all purposes.

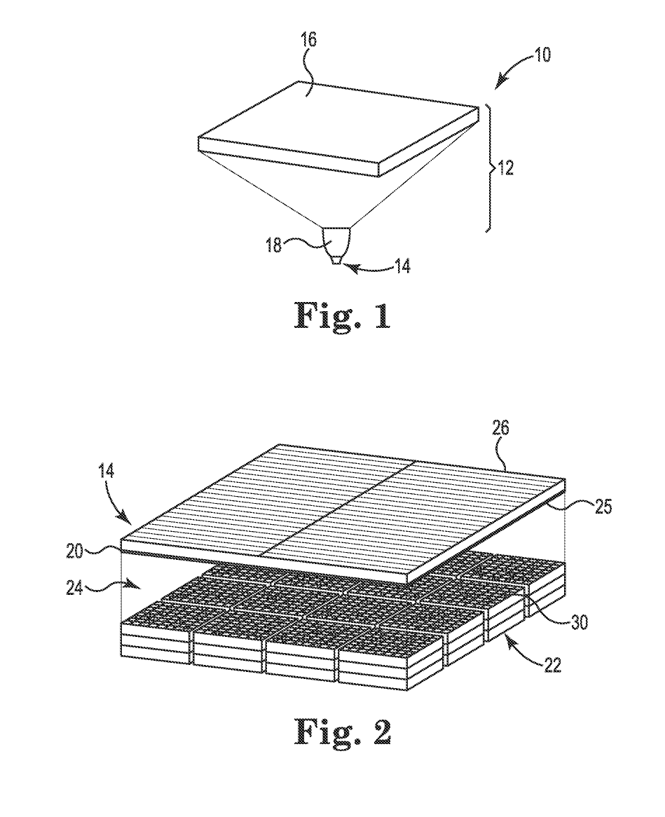

Referring now to the figures, and initially to FIGS. 1 through 3, an exemplary embodiment of a photovoltaic system 10 of the invention is illustrated, which generally includes an optional optical concentrator or optical concentrating module 12 and a light trapping optical module 14. System 10 can be used for photovoltaic conversion of incident light into electrical energy, as will be described in further detail below. If a concentrator is provided, the system 10 may optionally be referred to as a light trapping filtered concentrator.

Optical module 14 generally includes a dielectric slab or layer 24 that can capture light provided to it (e.g., by an optical concentrating module or directly by the sun) and deliver that light to multiple photovoltaic cells or sub-cells 22, 22′. The sub-cells used herein can vary in their structure, but generally include a single junction or multijunction photovoltaic solar cell that receives light of a specific range of wavelengths from an optical spectrum-splitting or filtering element and that has a bandgap or series of bandgaps that is matched to the range of wavelengths impinging upon it. For one example, red wavelengths are directed to a sub-cell having a bandgap that is optimized for red light, while green wavelengths are directed to a sub-cell that is optimized for green light, etc. Filters can optionally be used for the bandgap cells, which can give improved efficiency, depending on parasitic absorption in that cell.

In embodiments of the invention, a top cell 26 is provided, which is in contact with one side of the dielectric slab 24, while the sub-cells are in optical contact with the other side of the dielectric slab 24. In general, when elements of the module 14 are in optical contact with each other, they are in close physical contact, preferably where any gap is significantly less than the wavelength of light, which is also referred to herein as “operative contact.” In any case, it can be desirable to minimize the gaps or index of refraction differences between the various surfaces and/or to use multilayer coatings to reduce reflections.

One embodiment of dielectric slab 24 is a solid material that is electrically non-conducting and of high refractive index (i.e., greater than 2.0 at 550 nm, or preferably greater than 3.0 at 550 nm) such as GaP or titania, for example, although other materials are contemplated. In general, the material for the dielectric slab 24 can be any material with a relatively high index of refraction that is transparent to the wavelength of interest across most of the solar spectrum (i.e., the wavelengths that are lower in energy than those that are otherwise absorbed and converted into electrical energy by a top cell). This high index of refraction will help to trap the light that enters the slab 24 until it is absorbed by one of the sub-cells. The dielectric slab 24 includes texturing either on its top surface and/or scatterers within the slab to randomize the incoming light so that it is scattered in all directions. Such texturing can be provided as a physical texture on a surface of the slab, wherein the texture itself can either be random or much more ordered, such as can be accomplished with a microreplicated surface (e.g., an etched, microreplicated surface). Many types of configurations and arrangements can be used to provide the randomization of the light in addition to those described specifically herein.

The thickness of the dielectric slab can be chosen to have properties that allow it to achieve certain performance characteristics. For example, it can be desirable to provide a slab with a thickness that is at least as large as the width of the sub-cells. In one example, a system includes sub-cells that are approximately 1 mm on each side and a dielectric slab that is about 1 mm thick. For a relatively thin slab, the fraction of rays striking the same cell type twice in a row is relatively high as compared to a slab that is thicker.

As described herein, optical efficiency generally refers to the number of photons that pass through a spectral splitting element and are deposited onto the certain sub-cell divided by the total number of solar photons impinging on a top layer of the light trapping optical module. The system efficiency can be characterized by the amount of electrical energy produced by the device divided by the total amount of solar energy entering the device. For example, under a solar illumination of 1000 W/m², a device that produces 500 W of electrical energy has an overall efficiency of 50%.

A top surface 20 of the dielectric slab 24 may be adjacent to a layer 25, which can be an adhesive layer and/or an anti-reflective coating or layer that is provided so that incident light that reaches the slab is not reflected from the slab 24. The slab 24 further includes a top or first cell 26 above the top surface 20, which may be a light-absorbing, 2.2 eV GaP cell, for example, and which may be referred to as a “pre-blue” absorber. In an embodiment of the invention, the index of refraction of the slab 24 and the first cell 26 can provide for total internal reflection to trap the incident light in the slab 24 and the first cell 26 so that it impinges more than once upon the filtered sub-cells until it enters a sub-cell. It is noted that while the terms “first” and “top” are used relative to the cell 26, these terms are not meant to be limiting, as it is understood that one or more additional layers may be provided on the top or outside of this cell. The use of a cell 26 in combination with a dielectric slab allows for the index of refraction of the slab 24 to be higher since at least a portion of the light (e.g., at least a portion of the blue light and UV light) will be absorbed. That is, at least a portion of the high-energy light that would otherwise be absorbed in the slab will instead be absorbed by the first or top cell 26 so that it is not lost in the slab. Thus, in an embodiment of the invention, the first or top cell 26 is adjacent to the first surface of the dielectric slab, wherein the first or top cell 26 has a bandgap that is lower than an absorption energy onset of the dielectric slab, wherein the absorption energy onset occurs at the lowest energy (i.e., longest wavelength) where there is significant absorption in the material. Generally, the absorption is considered to be significant if the absorption length of light in the material is less than 10 times the thickness of the slab. The first or top cell 26 can further include an anti-reflective coating.

In a particular embodiment of the invention, the first or top cell 26 is optimized to the blue portion of the spectrum, since the efficiency of trapping light in a dielectric slab increases with increasing refractive index and materials with a high refractive index generally tend to absorb higher energy wavelengths, such as UV and blue, instead of being transparent over this region. Thus, if the blue/UV light is not absorbed by the first cell, it will be parasitically absorbed in the slab and lost. The use of the high-energy light-absorbing cell on the top of the dielectric slab allows the blue light to be selectively converted into electricity before the remainder of the light enters the dielectric slab. In this way, higher overall efficiency can be achieved by avoiding parasitic absorption of the blue/UV light in the high index slab.

The first or top cell 26 can be either a single junction cell or a multijunction cell. This cell 26 and the sub-cells 22, 22′ can be laminated or otherwise adhered to the dielectric slab 24 to minimize the number of interfaces between the cells and the slab. For example, having an air interface between the slab 24 and the sub-cells and/or light absorbing cell can lead to optical loss by undesirable reflection. One exemplary adhesive that can be used to attach these elements to each other is TiO2 sol gel, which provides a relatively high index to avoid undesirable reflections at the interfaces.

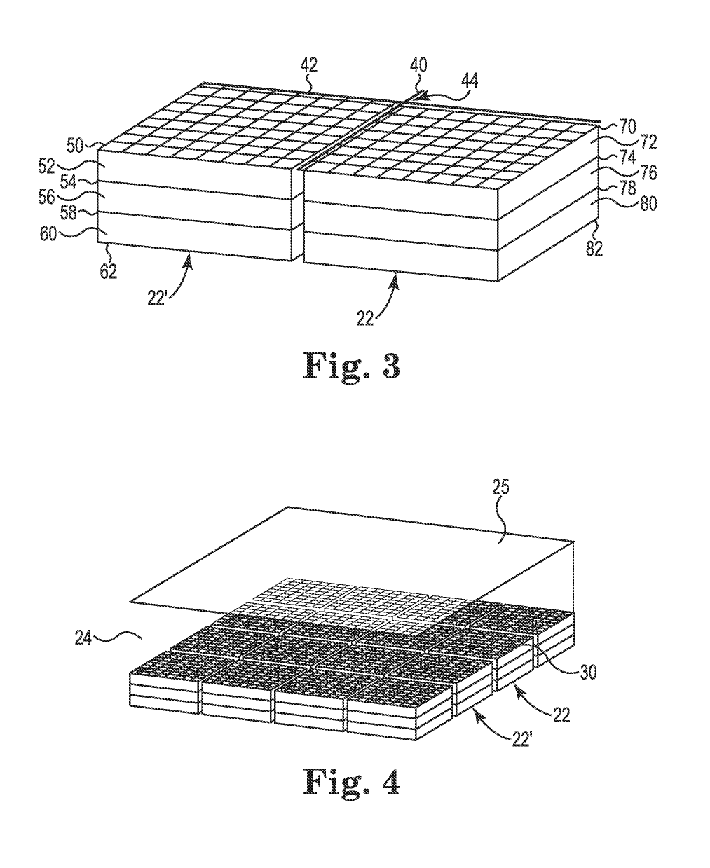

A configuration of an optical module of the invention can be provided without a first or top cell 26, in which case the index of refraction of the slab 24 would likely be at least slightly lower to minimize or avoid parasitic absorption of higher energy wavelengths in the slab 24. The system would generally be less efficient in solar energy conversion as compared to a configuration that does include a first or top cell 26. Such an embodiment is illustrated in FIG. 4, which is provided with a similar structure to that of FIG. 3, although the index of refraction of the slab 24 may be limited or lower due to the fact that a portion of the light is not absorbed before reaching the slab 24.

Referring again to FIG. 3, when the optical module 14 is provided with a top cell 26, this cell can be attached to the slab 24 in any number of ways, such as with adhesive layer 25 (e.g., titania sol-gel adhesive), or can alternatively be grown directly on the top of the slab 24 as a monolithic structure. Such an adhesive layer 25, when used, desirably can have a high index of refraction so that light can travel through it and into the slab 24 relatively easily. In one embodiment, the first or top cell 26 can be a single junction solar cell or photovoltaic cell, or can be a multijunction cell.

In order to maximize the trapping of light within a slab, additional reflectors can be provided on one or more of its sides. Alternatively, cells or cell stacks can be provided on one or more sides of the slab, although the sides would desirably be provided with filters for such a configuration, wherein such filters can be provided as a patterned surface on the sub-cells and/or the side(s) of the slab 24.

The light trapping optical module 14 further includes multiple photovoltaic sub-cells 22, 22′, each of which is tuned to photovoltaically absorb a predefined subset of the light spectrum. As shown, each of the sub-cells 22, 22′ can be a multijunction solar cell, or more specifically, a triple junction solar cell. As is best illustrated in FIG. 3, a first cell stack 22 is positioned adjacent to a second cell stack 22′, and each cell stack includes three stacked cells with three junctions within a single cell structure, thereby providing six differently tuned photovoltaic cells for the overall system (although when a top cell is provided, it will provide for a seventh photovoltaic cell of the system, which also may be tuned differently than any of the other six cells). A space may be provided between each of the cells 22 and an adjacent cell 22′ to electrically insulate the cells, such as can be provided with an insulating material (e.g., a UV-cured dielectric polymer or functional equivalent) that maintains cells in a spaced arrangement. In one embodiment, the cells are considered to be adjacent to each other in that they are positioned very close to each other without actually being in electrical contact with each other. That is, the cells can be spaced from each other by distances of between 1 micron and 1 mm, or may be closer to each other, such as in the range of 1 to 100 microns. In general, each cell stack is designed to respond most efficiently to certain wavelengths of light of the incident light that are directed to it.

In the illustrated exemplary embodiment, second cell stack 22′ includes a number of layers, including a front contact grid 50, a first cell 52, a second cell 56, and a third cell 60, with a first tunnel junction 54 between the first cell 52 and second cell 56, a second tunnel junction 58 between the second cell 56 and the third cell 60, and a rear contact 62. The adjacent first cell stack 22 also includes a number of layers, including a front contact grid 70, a first cell 72, a second cell 76, and a third cell 80, with a first tunnel junction 74 between the first cell 72 and second cell 76, a second tunnel junction 78 between the second cell 76 and the third cell 80, and a rear contact 82.

With continued reference to the exemplary embodiment of the cell stacks of FIG. 3, the first cell 52 of the second cell stack 22′, which is the uppermost cell of this stack 22′, is tuned (e.g., it has bandgap characteristics) to absorb the spectral bandwidth portion of incident light including wavelengths ranging from 670 nm to 564 nm, and can have a 1.85 eV bandgap. The spectral bandwidth portion of the incident light that is outside of this wavelength range will travel to the adjacent cell 56. The second cell 56 of the second cell stack 22′, which is the middle cell of this stack 22′, is tuned (e.g., it has bandgap characteristics) to absorb the spectral bandwidth portion of incident light including wavelengths ranging from 785 nm to 670 nm, and can have a 1.58 eV bandgap. The spectral bandwidth portion of the incident light that is outside of this wavelength range will travel to the adjacent cell 60. The third cell 60 of the second cell stack 22′, which is the lowermost cell of this stack 22′, is tuned (e.g., it has bandgap characteristics) to absorb the spectral bandwidth portion of incident light including wavelengths ranging from 898 nm to 785 nm, and can have a 1.38 eV bandgap.

As discussed above, first cell stack 22 is adjacent to second cell stack 22′, wherein the first cell 72 of the first cell stack 22, which is the uppermost cell of this stack 22, is tuned (e.g., it has bandgap characteristics) to absorb the spectral bandwidth portion of incident light including wavelengths ranging from 1088 nm to 898 nm, and can have a 1.14 eV bandgap. The spectral bandwidth portion of the incident light that is outside of this wavelength range will travel to the adjacent cell 76. The second cell 76 of the first cell stack 22, which is the middle cell of this stack 22, is tuned (e.g., it has bandgap characteristics) to absorb the spectral bandwidth portion of incident light including wavelengths ranging from 1333 nm to 1088 nm, and can have a 0.93 eV bandgap. The spectral bandwidth portion of the incident light that is outside of this wavelength range will travel to the adjacent cell 80. The third cell 80 of the first cell stack 22, which is the lowermost cell of this stack 22, is tuned (e.g., it has bandgap characteristics) to absorb the spectral bandwidth portion of incident light including wavelengths ranging from 1771 nm to 1333 nm, and can have a 0.70 eV bandgap. These described wavelength ranges and associated bandgaps are intended only to provide an exemplary device configuration and it is understood that embodiments of the invention can include cells or cell stacks having characteristics that are at least slightly different from those of this described embodiment.

The first cell or cell stack 22 further can include a bus bar 40, which can be provided for the cells with a relatively low bandgap, and the second cell or cell stack 22′ can include a bus bar 42, which can be provided for the cells having a relatively high bandgap. An isolated crossing 44 is located at the point where the bus bars 40, 42 intersect. Alternatively, other contacting methods and configurations can be used, such as non-crossing isolated contacts to backside conduction pathways, for example.

As shown, the sub-cells 22, 22′ are arranged in an alternating or “checkerboard” type of pattern across the length and width of the optical module 14. As is also illustrated in FIG. 2, the optical module 14 can include one or more filters 30 positioned generally between the dielectric slab 24 and the sub-cells 22, 22′. Such filter(s) 30 are provided to be sure that the light is directed to the correct sub-cells, wherein light that is not directed to the correct sub-cell should be reflected. In order to provide the desired filtering, the textured slab may be provided with a checkerboard pattern of filters that correspond to and are aligned with the cell arrangement such that a first set of sub-cells is aligned with a first set of filters and a second set of sub-cells is aligned with a second set of filters. In an alternative arrangement, the checkerboard pattern may consist of filters on the cell or cell stack having the relatively low bandgap (e.g., cell or cell stack 22), wherein some of the photons with low energy will be parasitically absorbed by the cell or cell stack having a relatively high bandgap (e.g., cell stack 22′). In embodiments of the photovoltaic system, adjacent cells of the checkerboard pattern are receptive to different wavelengths from a spectral splitter. This increases the probability that a photon with the desired wavelength will strike a particular sub-cell with the fewest number of internal reflections within the dielectric slab 24. The filters can have a number of different embodiments, such as a multilayer dielectric stack, a grating, and a photonic crystal, all of which may or may not be fully periodic.

Filters used with the module 14 can be two or three dimensional photonic crystal type filters, for example, which can be chosen to achieve better omindirectionality as compared to a simple layered filter, or a one-dimensional photonic crystal. While a one-dimensional photonic crystal may be capable of achieving omnidirectional performance, such a filter may be less effective when light is incident from a high index material, such as the high index slab described herein, and is therefore also contemplated for use with the invention. Photonic crystals can have a variety of different structures and properties, but as described herein, are generally composed of periodic dielectric nanostructures that affect the propagation of electromagnetic waves by defining allowed and forbidden electronic energy bands. Essentially, photonic crystals contain regularly repeating internal regions of high and low dielectric constant. Photons (behaving as waves) may propagate through this structure, depending on their wavelengths. Wavelengths of light that are allowed to travel are known as modes, and groups of allowed modes can form bands. Disallowed bands of wavelengths are called photonic band gaps, which give rise to distinct optical phenomena, such as inhibition of spontaneous emission, high-reflecting omnidirectional mirrors, and low loss waveguiding, for example. Since basic physical phenomena are based on diffraction, the periodicity of the photonic crystal structure and the dielectric features can be of approximately the same length-scale of the electro-magnetic waves in the photonic crystal material (i.e., ¼ of the wavelength in the material for a one-dimensional photonic crystal mirror).

Each of the photovoltaic cells of the module 14 can include a number of features, such as a central cell active region, a back contact and reflector, one or more contact grid areas, a layer that can include an antireflective coating/filter and/or adhesive. Each of the photovoltaic cells is generally tuned or has bandgap characteristics that allow it to absorb a certain spectral bandwidth portion of the incident light to which it is subjected, and can include a reflector at either the top or bottom of the cell that allows it to reflect the portion that is not absorbed. In operation, the photovoltaic cells are arranged so that the entering and reflecting light will be absorbed and reflected from the highest energy down to the lowest energy in each of the cell stacks (e.g., blue is absorbed before green, orange is absorbed before red, etc.).

As is described above, the optical module 14 is illustrated and described as having two different cell stacks, each of which includes three bandgaps to thereby utilize six different solar cells in the module, when the first cell is not considered. However, more or less than two of such cell stacks can instead be provided for a particular optical module, wherein the particular subset of the light spectrum that each of the cells will absorb and reflect will then be different than that described above for a six junction structure. In addition, the wavelength ranges associated with each of the solar cells described above can either be smaller or larger, depending on the particular materials used, the tuning of the system, and the location of the system, etc.

One or more photovoltaic systems of the invention can be made into a module that includes multiple systems. The systems themselves and/or the modules in which they are included can in turn be mounted to a common framework, wherein the entire framework and/or individual modules can optionally include tracking or non-tracking features, depending on the system and the desired performance thereof.

The relatively high efficiencies that can be achieved by the photovoltaic systems of the invention occur for a number of reasons. For one reason, the solid material of the dielectric slab can provide increased efficiencies in optically coupling incident light to the solar cells and randomizing the light allows it to be trapped within the slab due to a high index of refraction that is possible due to a cell (e.g., a blue cell) on top. For another reason, the effective splitting of the light spectrum is performed in such a way that each solar cell receives a specific subset of the light spectrum that is most efficiently absorbed by it. The filters used can be omnidirectional filters such that they can cut off the appropriate wavelengths of light relatively efficiently over a wide range of angles. With such an omnidirectional filter, the angle-averaged reflection and transmission would be relatively high in the relevant bands.

The above-described optical module 14 can optionally be provided with an optical concentrating module 12, which can include one or more concentrators. In an exemplary system that uses two concentrators, both a primary optic or concentrator 16 and a secondary optic or concentrator 18 are provided. The illustrated primary concentrator 16 is a Fresnel lens, while the secondary concentrator 18 is a compound parabolic concentrator. With regard to the primary concentrator 16, any type of lens or concentrator may be used instead of a Fresnel lens, although a Fresnel lens can provide an efficient manner of concentrating incident light from a relatively large surface area lens (e.g., 30 cm wide by 30 cm long) to an area that is considerably smaller with a lens that is considerably lighter than a traditional lens. Thus, either a standard lens or a Fresnel lens can efficiently focus light from a large to a small area to provide a desired level of concentration, while the lightweight Fresnel lens may provide some structural benefits. Secondary concentrators or optics, if desired, can then use this concentrated light that is output from the primary concentrator and concentrate it further. In this exemplary embodiment, the secondary concentrator 16 is positioned such that its upper surface is spaced from the bottom surface of the Fresnel lens by a distance of approximately 30 cm, although the distance can vary considerably depending on the properties of the primary concentrator 12 and the desired efficiency of the system. With the use of a concentrator like a Fresnel lens, a large surface area of a lens is exposed to incident light and concentrated to an area that corresponds to an input area of the secondary concentrator 18.

Although the secondary concentrator 18 is illustrated in this embodiment as a compound parabolic concentrator, other or additional secondary/tertiary concentrators can instead or additionally be used. For one example, the secondary concentrator can be a parabolic concentrator characterized as a flat-sided light funnel, which will typically provide less optical efficiency than a compound parabolic concentrator, but still can provide acceptable efficiency. The relative shape and size of secondary concentrator 18 that is illustrated is intended to be exemplary in that the concentrator can include a number of different curvilinear shapes for its concentrator region other than the shape that is illustrated. The shapes and sizes of the features of the secondary concentrator 18 are designed and chosen to optimize the concentration of light that enters the system and provided to the optical module 14. In an alternative aspect of the invention, the system 10 will not include multiple optical concentrators acting in series, but will instead include only a single or primary optical concentrator, such as a system that includes concentration only with a compound parabolic concentrator. It is further understood that additional concentrators (e.g., a tertiary concentrator) may be used in series with primary and secondary concentrators illustrated and described relative to this exemplary embodiment.

The quantity and types of concentrators provided for a particular optical concentrating module 12 are selected to provide a predetermined desired concentrating power over a certain range. For example, the concentrating power of concentrator 12 can include a concentration of between 100× and 1000×. However, concentration levels below 100× or above 1000× are considered to be within the scope of the invention. The selected levels of concentration can provide a concentrating module 12 that is relatively compact while minimizing the heat load and cost of components. The illustrated concentrating module is only one exemplary concentration device or system, where it is understood that many types of concentration systems can be used alternatively or in addition to the illustrated and described concentrators. The light trapping optical module 14 is located below the output end of the concentrating module 12 and is positioned so that the output end of the module 12 is in optical communication with the light trapping module 14, which is best illustrated in the enlarged view of FIG. 2, for example.

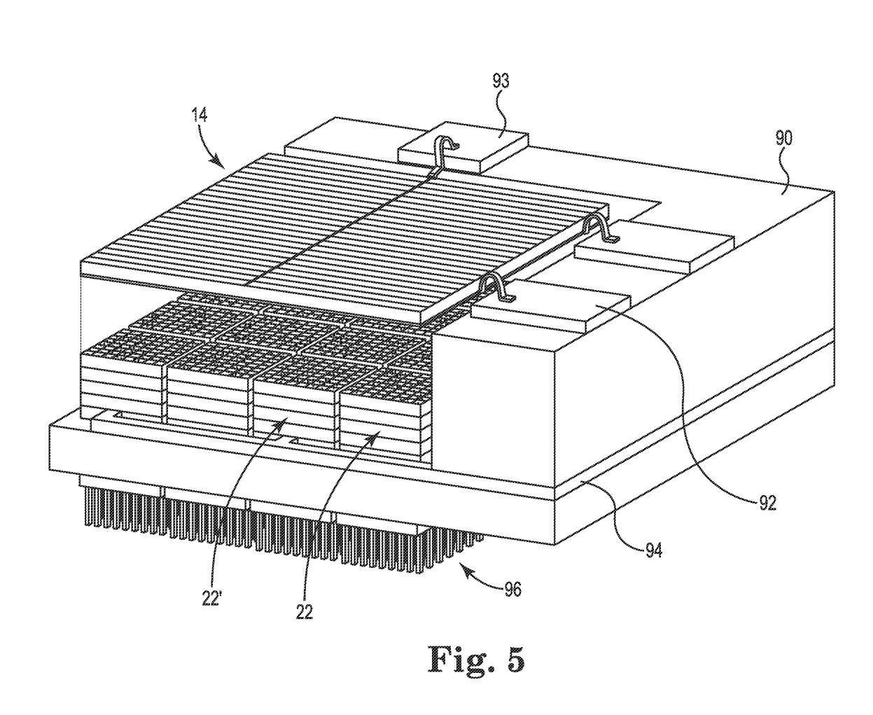

FIG. 5 is a perspective view of a light trapping filtered concentrator of the invention as it can be incorporated into a multilayer printed circuit board 90. In particular, a light trapping optical module 14 is illustrated with an interconnect 92 to the top cell bus bars, and interconnect 93 to the top cell rear contact, and an interconnect 94 to the back or rear contacts. A rear-mounted heatsink 96 is also illustrated in an exemplary relationship relative to the cell stacks 22, 22′ of the module 14.

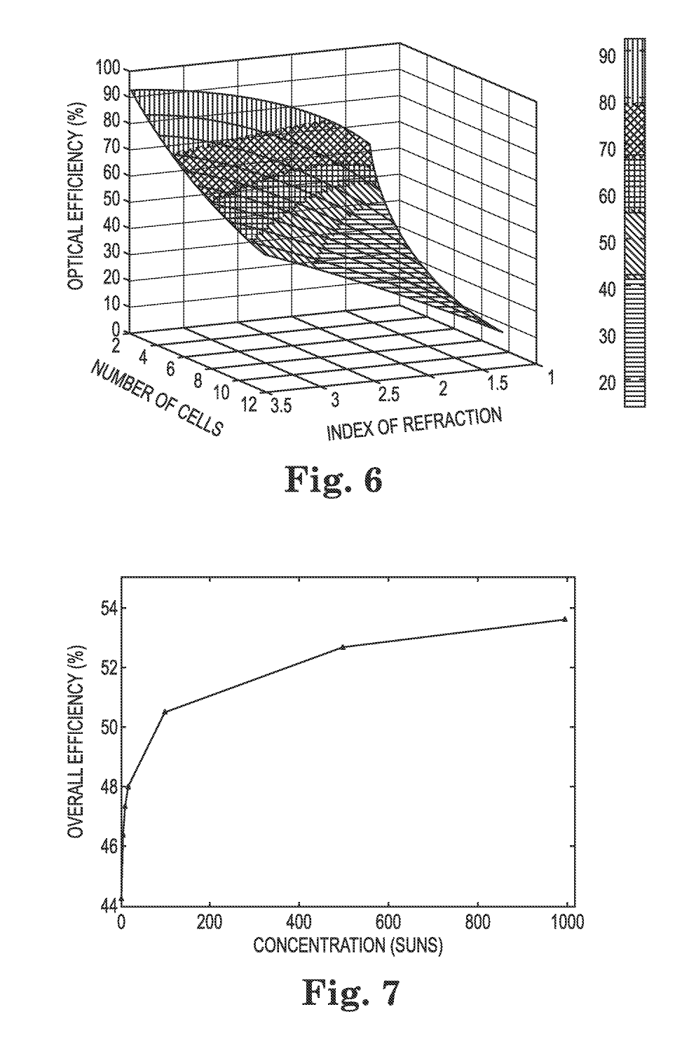

FIG. 6 is a three-dimensional graph expressing the design space for maximizing optical efficiency with respect to the number of cells and index of refraction of a light trapping dielectric slab. In particular, the graph illustrates the need for high index material for the slab and a relatively low number of sub-cells to achieve relatively high optical efficiency. For one example, a system provided with two sub-cells below a slab that has a refractive index of 1.5 (e.g., glass (SiO₂)) was calculated to have an optical efficiency of approximately 69%, while a system with five sub-cells below the slab that also has a refractive index of 1.5 was calculated to have an optical efficiency of approximately 36%. In yet another example, a system provided with two sub-cells below a slab having a refractive index of approximately 3.5 (e.g., GaP) was calculated to have an optical efficiency of approximately 92%.

FIG. 7 is a graph expressing exemplary device efficiency as a function of concentration using devices and concepts of the present invention.

The present invention has now been described with reference to several embodiments thereof. The entire disclosure of any patent or patent application identified herein is hereby incorporated by reference. The foregoing detailed description and examples have been given for clarity of understanding only. No unnecessary limitations are to be understood therefrom. It will be apparent to those skilled in the art that many changes can be made in the embodiments described without departing from the scope of the invention. Thus, the scope of the present invention should not be limited to the structures described herein, but only by the structures described by the language of the claims and the equivalents of those structures.

1. A photovoltaic system that converts incident light into electrical energy, the system comprising:
a light trapping optical module comprising:
a light randomizing dielectric slab having a first surface and a second surface;
a first cell adjacent to the first surface of the dielectric slab, wherein the first cell comprises a bandgap of lower energy than the energy of absorption onset of the dielectric slab;
at least one filter element in optical contact with the second surface of the dielectric slab; and
a sub-cell array comprising a plurality of photovoltaic sub-cells,
wherein at least one of the sub-cells comprises a first surface that is in optical contact with the at least one filter element.

2. The photovoltaic system of claim 1, wherein the bandgap of the first cell is higher than a bandgap of at least one of the plurality of sub-cells.

3. The photovoltaic system of claim 1, wherein the second surface of the dielectric slab comprises multiple filter elements, and wherein each of the multiple filter elements is in optical contact with one of the plurality of sub-cells.

4. The photovoltaic system of claim 1, wherein the second surface of the dielectric slab comprises the at least one filter element.

5. The photovoltaic system of claim 1, wherein the first surface of at least one of the plurality of sub-cells comprises the at least one filter element.

6. The photovoltaic system of claim 1, wherein the at least one filter element comprises one of a multilayer dielectric stack, a grating, and photonic crystals.

7. The photovoltaic system of claim 1, wherein the at least one filter element comprises an omnidirectional filter element.

8. The photovoltaic system of claim 1, wherein each of the plurality of sub-cells comprises a multijunction cell.

9. The photovoltaic system of claim 1, wherein the plurality of sub-cells comprises an array of stacked photovoltaic cells.

10. The photovoltaic system of claim 1, wherein the plurality of sub-cells comprises a first plurality of sub-cells having a first bandgap and a second plurality of sub-cells having a second bandgap, and wherein the at least one filter element comprises first and second filter elements, each of which corresponds to one of the first and second pluralities of sub-cells.

11. The photovoltaic system of claim 1, wherein a first surface of the first cell comprises an antireflective material.

12. The photovoltaic system of claim 1, in combination with a printed circuit board.

13. The photovoltaic system of claim 1, wherein an index of refraction of the dielectric slab is greater than 2.0 at a wavelength of 550 nm, and wherein the index of refraction of the dielectric slab and the first cell provide for total internal reflection that traps incident light in the dielectric slab and the first cell.

14. The photovoltaic system of claim 1, further comprising an optical concentrating module comprising an input area into which incident light enters the concentrating module, and an output area from which concentrated light exits the concentrating module, wherein the output area is in optical communication with the optical module.

15. The photovoltaic system of claim 1, wherein each of the sub-cells of the sub-cell array are spaced from and electrically insulated from each adjacent sub-cell by an insulating material.
